(19) United States
(12) Patent Application Publication
(10) Pub. No.: US 2025/0282612 A1
(43) Pub. Date: Sep. 11, 2025

(54) PACKAGE STRUCTURE

(71) Applicant: Advanced Semiconductor Engineering, Inc., Kaohsiung (TW)

(72) Inventor: Ying-Chung CHEN, Taoyuan (TW)

(73) Assignee: Advanced Semiconductor Engineering, Inc., Kaohsiung (TW)

(21) Appl. No.: 18/600,579

(22) Filed: Mar. 8, 2024

(51) Int. Cl. B81B 7/00; B81C 1/00; H01L 23/00

(52) U.S. Cl. CPC B81B 7/0077; B81C 1/00269; B81B 2207/012; B81B 2207/096; H01L 24/05; H01L 24/06; H01L 24/32; H01L 24/48; H01L 24/49; H01L 24/73; H01L 2224/05553; H01L 2224/05554; H01L 2224/0603; H01L 2224/06051; H01L 2224/32145; H01L 2224/32225; H01L 2224/48091; H01L 2224/48145; H01L 2224/48227; H01L 2224/49175; H01L 2224/73215; H01L 2224/73265; H01L 2924/1433; H01L 2924/1461

(57) ABSTRACT

A package structure is provided. The package structure includes a substrate structure, a chip, an encapsulant, and an adhesive element. The substrate structure defines a cavity. The chip is disposed in the cavity. The encapsulant encapsulates the chip. The adhesive element is disposed over a top surface of the substrate structure, wherein the substrate structure includes a barring structure between the encapsulant and the adhesive element and configured to reduce a contact between the encapsulant and the adhesive element.

### BACKGROUND

### 1. Technical Field

The present disclosure relates generally to a package structure.

### 2. Description of the Related Art

Along with the increasing technical advance of package technology, package sizes are decreased, and various structures are developed. For example, MEMS packages are provided with advantages of high strength, high performance, and low cost; thus the development of MEMS packages has become increasingly important in package technology.

Open cavity mold packages or open cavity pre-mold packages are widely used for IC packaging and IC assemblies. However, formation of the mold structure requires delicate mold tools and thus the manufacturing complexity as well as the cost may increase, package sizes may increase, and device density may decrease.

### SUMMARY

In one or more arrangements, a package structure includes a substrate structure, a chip, an encapsulant, and an adhesive element. The substrate structure defines a cavity. The chip is disposed in the cavity. The encapsulant encapsulates the chip. The adhesive element is disposed over a top surface of the substrate structure, wherein the substrate structure includes a barring structure between the encapsulant and the adhesive element and configured to reduce a contact between the encapsulant and the adhesive element.

In one or more arrangements, a package structure includes a substrate structure, a sensing device, and a gel. The substrate structure includes a lower substrate, a middle substrate, and an upper substrate laminated to each other and collectively defining a cavity. The sensing device is disposed in the cavity. The gel covers the sensing device and is spaced apart from an upper surface of the substrate structure.

In one or more arrangements, a package structure includes a substrate, a sidewall, a chip, an encapsulant, and a cap. The sidewall is disposed over the substrate, and the sidewall and the substrate collectively define a cavity. The chip is disposed in the cavity. The encapsulant is disposed in the cavity and encapsulates the chip. The cap is disposed over the sidewall, wherein an outer lateral surface of the sidewall is substantially aligned with a lateral surface of the substrate.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a top view of a package structure in accordance with some arrangements of the present disclosure.

FIG. 1C is a top view of a package structure in accordance with some arrangements of the present disclosure.

FIG. 1D is a cross-section of a package structure in accordance with some arrangements of the present disclosure.

FIG. 1E is a cross-section of a package structure in accordance with some arrangements of the present disclosure.

FIG. 1F is a cross-section of a package structure in accordance with some arrangements of the present disclosure.

FIG. 1G is a cross-section of a package structure in accordance with some arrangements of the present disclosure.

FIG. 1H is a cross-section of a package structure in accordance with some arrangements of the present disclosure.

FIG. 2A is a cross-section of a package structure in accordance with some arrangements of the present disclosure.

FIG. 2B is a cross-section of a package structure in accordance with some arrangements of the present disclosure.

FIG. 2C is a cross-section of a package structure in accordance with some arrangements of the present disclosure.

FIG. 3A, FIG. 3B, FIG. 3C, FIG. 3D, FIG. 3E, FIG. 3F, FIG. 3G, and FIG. 3H illustrate various stages of an exemplary method for manufacturing a package structure in accordance with some arrangements of the present disclosure.

FIG. 4A and FIG. 4B illustrate various stages of an exemplary method for manufacturing a package structure in accordance with some arrangements of the present disclosure.

FIG. 5A, FIG. 5B, and FIG. 5C illustrate various stages of an exemplary method for manufacturing a package structure in accordance with some arrangements of the present disclosure.

FIG. 6A and FIG. 6B illustrate various stages of an exemplary method for manufacturing a package structure in accordance with some arrangements of the present disclosure.

FIG. 7A and FIG. 7B illustrate various stages of an exemplary method for manufacturing a package structure in accordance with some arrangements of the present disclosure.

Common reference numerals are used throughout the drawings and the detailed description to indicate the same or similar elements.

### DETAILED DESCRIPTION

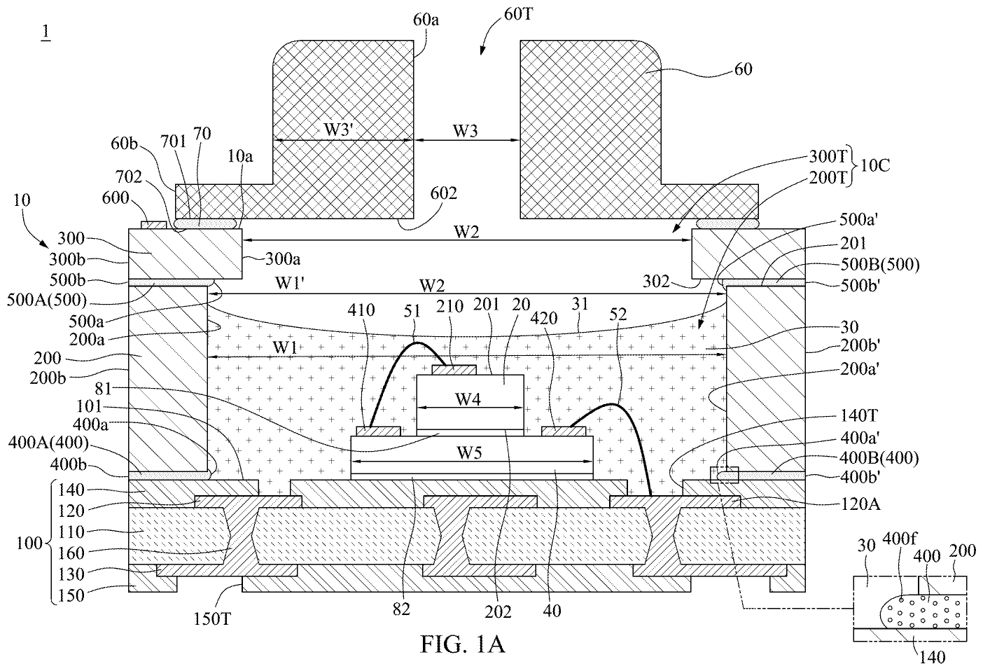

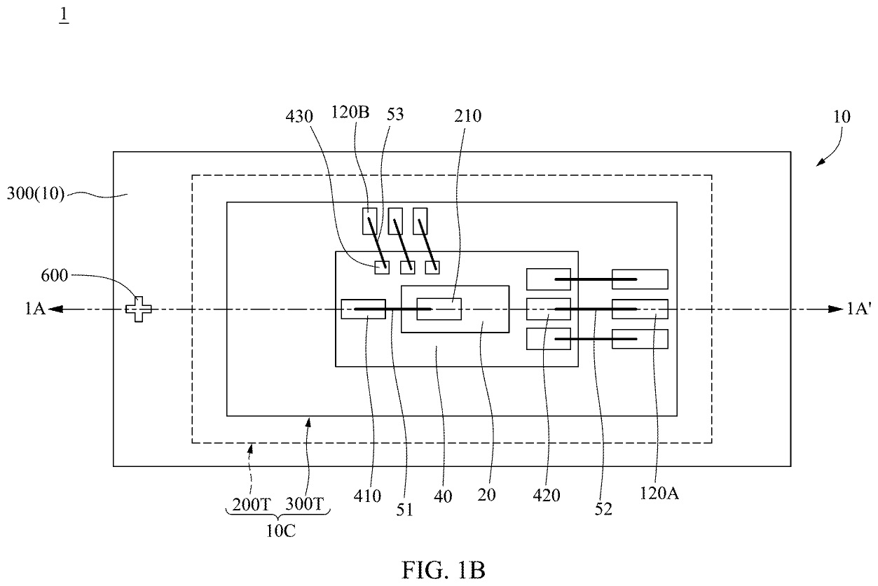

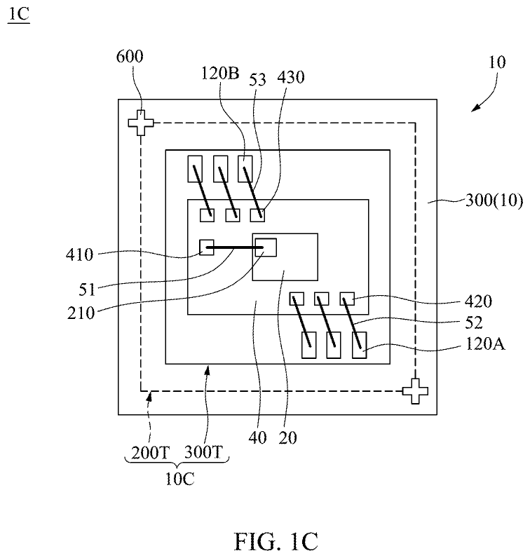

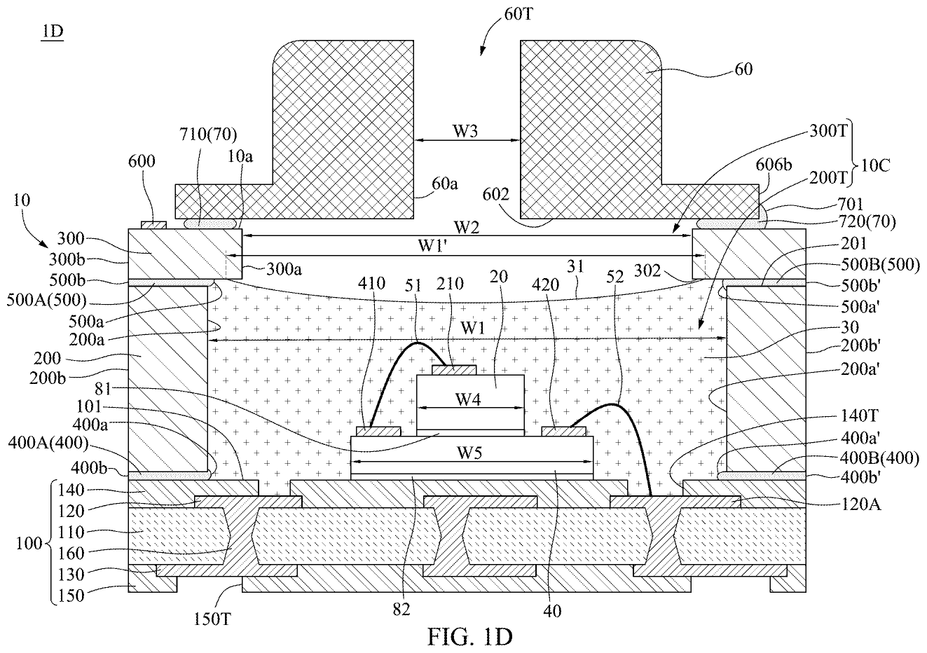

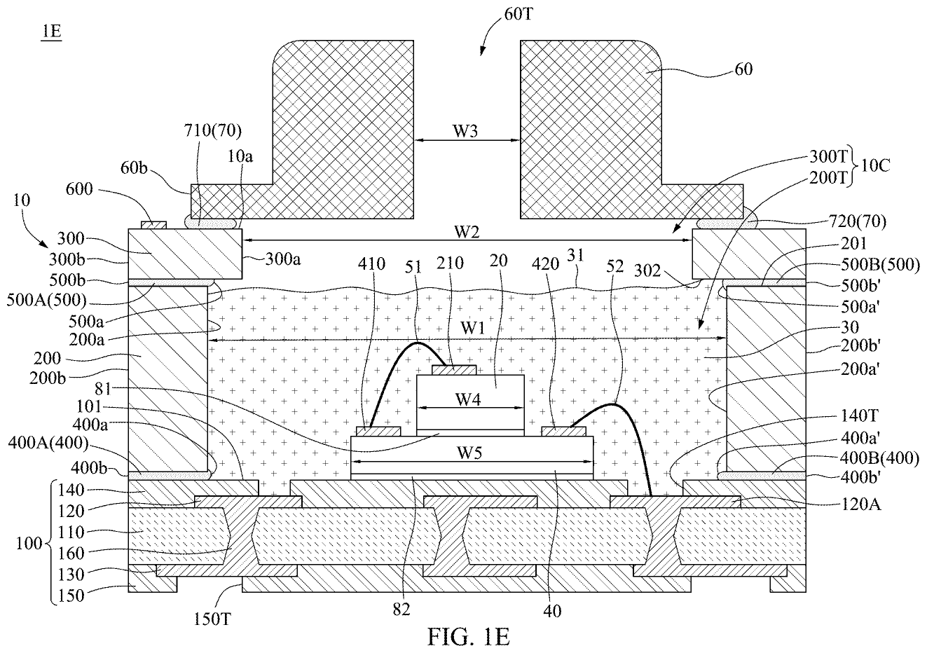

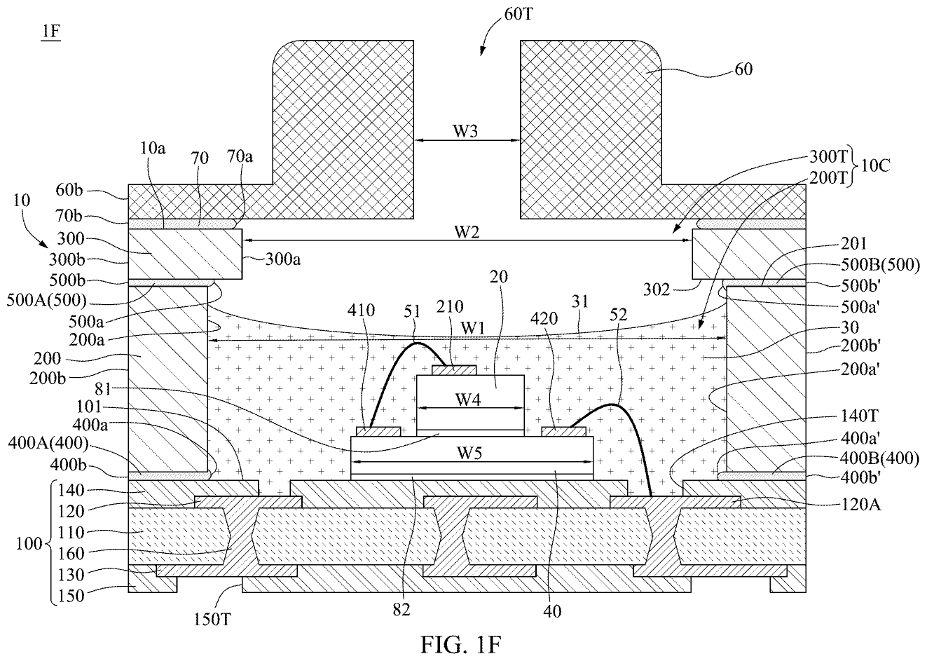

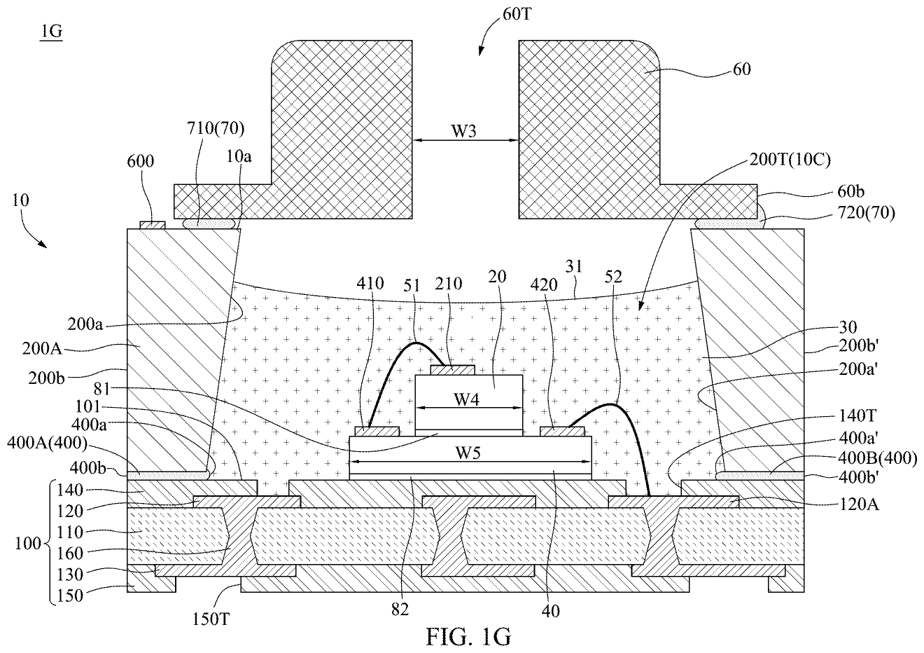

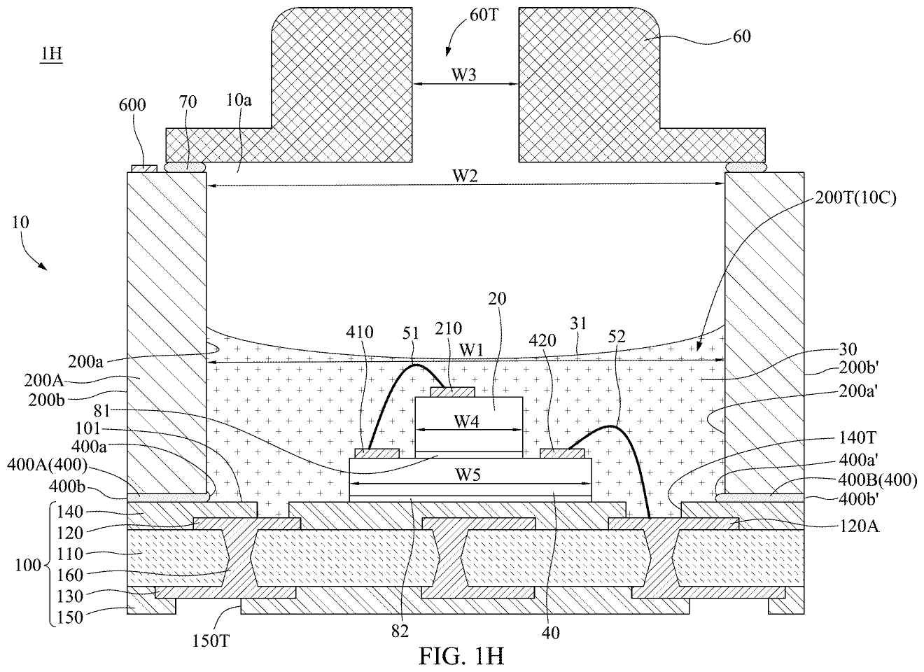

FIG. 1A is a cross-section of a package structure 1 in accordance with some arrangements of the present disclosure. FIG. 1B is a top view of a package structure 1 in accordance with some arrangements of the present disclosure. In some arrangements, FIG. 1A is a cross-section along a line 1A-1A′ in FIG. 1A. The package structure 1 may include a substrate structure 10, chips 20 and 40, an encapsulant 30, conductive wires 51, 52, and 53, a lid 60, and an adhesive element 70.

The substrate structure 10 may include a plurality of substrates laminated to each other. In some arrangements, the substrate structure 10 includes substrates 100, 200, and 300, adhesive elements 400 and 500, and an alignment mark 600. In some arrangements, the substrate 100 is adhered to the substrate 200 through the adhesive element 400, and the substrate 200 is adhered to the substrate 300 through the adhesive element 500. In some arrangements, the substrate structure defines a cavity 10C.

In some arrangements, each of the substrates 100, 200, and 300 may independently include, for example, a printed circuit board, such as a paper-based substrate layer, a composite substrate layer, or a polymer-impregnated glass-fiber-based substrate layer. Each of the substrates 100, 200, and 300 may independently include an interconnection structure, which may include such as a plurality of conductive traces and/or a plurality of conductive vias. The interconnection structure may include a redistribution layer (RDL) and/or a grounding element. In some arrangements, each of the substrates 100, 200, and 300 may independently include an organic substrate or a leadframe. In some arrangements, each of the substrates 100, 200, and 300 may independently include a two-layer substrate which includes a core layer and a conductive material and/or structure disposed on an upper surface and a bottom surface of the substrate. Each of the substrates 100, 200, and 300 may independently include one or more electronic components. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. Each of the substrates 100, 200, and 300 may independently include one or more conductive elements, surfaces, contacts, or pads.

In some arrangements, the substrate 100 includes a core layer 110, conductive layers 120 and 130 on opposite surfaces of the core layer 110, dielectric layers 140 and 150 on the conductive layers 120 and 130, respectively, and a conductive structure 160 electrically connecting the conductive layer 120 to the conductive layer 130. In some arrangements, the dielectric layer 140 defines an opening 140T exposing at least a portion of a conductive pad 120A of the conductive layer 120. In some arrangements, the dielectric layer 150 defines an opening 150T exposing at least a portion of the conductive layer 130. The substrate 100 may be referred to as a lower substrate configured to support the chips 20 and 40.

In some arrangements, the substrate 200 is disposed on the substrate 100. In some arrangements, the substrate 200 is laminated to the substrate 100. In some arrangements, the substrate 200 is disposed between the substrate 100 and the substrate 300. In some arrangements, the substrate 200 has or defines a through hole 200T (also referred to as “an opening” or “a cavity”) exposing a portion of a top surface (e.g., a surface 101) of the substrate 100. In some arrangements, the substrates 100 and 200 collectively may be referred to or construct a multi-layered substrate. In some arrangements, the substrates 100 and 200 collectively define a cavity (e.g., the through hole 200T). In some arrangements, an outer lateral surface (e.g., a surface 200b) of the substrate 200 is substantially aligned with a lateral surface (e.g., a surface 100b) of the substrate 100. The substrate 200 may be referred to as a middle substrate or a sidewall of the substrate structure 10.

In some arrangements, the substrate 300 is connected to the substrates 100 and 200. In some arrangements, the substrate 300 is laminated to the substrate 200. In some arrangements, the substrate 300 has or defines a through hole 300T (also referred to as “an opening” or “a cavity”) connected to the through hole 200T. In some arrangements, the through hole 300T is over and vertically overlapping the chip 20. In some arrangements, the through hole 300T defines an opening of the cavity 10C and vertically overlapping the chip 20, for example, in a direction substantially perpendicular to a surface 10a of the substrate structure 10. In some arrangements, the through hole 300T connects the cavity 10C to outside the cavity 10C. In some arrangements, the substrates 100, 200, and 300 are laminated to each other and collectively define the cavity 10C of the substrate structure 10. In some arrangements, the through holes 200T and 300T collectively define the cavity 10C of the substrate structure 10. In some arrangements, a width W2 of the through hole 300T is less than a width W1 of the through hole 200T in a cross-sectional view. In some arrangements, a lateral sidewall (e.g., a surface 300b) of the substrate 300 is substantially aligned with lateral sidewalls of the substrates 100 and 200. In some arrangements, a lateral sidewall (e.g., a surface 300a) of the substrate 300 is protruded out of the substrate 200 and overhanging over the through hole 200T. The substrate 300 may be referred to as an upper substrate, a cap substrate, a cap, or a roof element. In some arrangements, a bottom surface (e.g., a surface 302) of the substrate 300 (or the roof element) defines an inner top surface of the cavity 10C.

In some arrangements, the adhesive element 400 adheres the substrate 100 (or the lower substrate) to the substrate 200 (or the middle substrate) and is exposed to the cavity 10C. In some arrangements, the adhesive element 400 includes portions 400A and 400B on opposite sides of the chip 20 in a cross-sectional view perspective. In some arrangements, the portion 400A of the adhesive element 40 has a surface 400a exposed to and protruded toward the cavity 10C. In some arrangements, the portion 400A of the adhesive element 40 has a surface 400b opposite to the surface 400a and substantially aligned with an outer lateral surface (e.g., the surface 200b) of the substrate 200. In some arrangements, the surface 400b is substantially aligned with an outer lateral surface (e.g., the surface 100b) of the substrate 100. In some arrangements, the surface 400b is substantially aligned with an outer lateral surface (e.g., the surface 300b) of the substrate 300. In some arrangements, the portion 400A covers a portion of the inner sidewall (e.g., a surface 200a) of the cavity 10C. In some arrangements, the portion 400B of the adhesive element 40 has a surface 400a′ exposed to and protruded toward the cavity 10C. In some arrangements, the portion 400B of the adhesive element 40 has a surface 400b′ opposite to the surface 400a′ and substantially aligned with an outer lateral surface (e.g., the surface 200b) of the substrate 200. In some arrangements, the surface 400b′ is substantially aligned with an outer lateral surface (e.g., a surface 300b) of the substrate 300. In some arrangements, the portions 400A and 400B are protruded toward or into the cavity 10C by different lengths. In some arrangements, the surfaces 400a and 400a′ of the adhesive element 400 are protruded out of or beyond the inner lateral surface (e.g., the surfaces 200a and 200a′) of the substrate 200 (or the sidewall). The protrusions of the adhesive element 400 may be resulted from the thermal-compression operation in which the substrate 200 is pressed toward the substrate 100 and the adhesive element 400 disposed there-between is softened upon heating and then deformed under the pressure. In some arrangements, the adhesive element 400 may be or include an epoxy-based material, e.g., an epoxy-based resin. In some arrangements, the adhesive element 400 includes fillers 400f. The adhesive element 400 may be referred to as an adhesive resin, a lower adhesive element, or a lower adhesive resin.

In some arrangements, the adhesive element 500 adheres the substrate 300 (or the upper substrate) to the substrate 200 (or the middle substrate) and is exposed to the cavity 10C. In some arrangements, a width of the adhesive element 500 is less than a width of the bottom surface of the substrate 300 (or the cap) in a cross-sectional view perspective. In some arrangements, the substrate 300 (or the cap substrate) is adhered to the multi-layered substrate (e.g., the combination of the substrates 100 and 200) through the adhesive element 500. In some arrangements, the adhesive element 500 includes portions 500A and 500B on opposite sides of the chip 20 in a cross-sectional view perspective. In some arrangements, a width of the adhesive element 500 is greater than a minimum width of the substrate 200 (or the sidewall) in a cross-sectional view perspective. In some arrangements, the portion 500A of the adhesive element 50 has a surface 500a exposed to and protruded toward the cavity 10C. In some arrangements, the portion 500A of the adhesive element 50 has a surface 500b opposite to the surface 500a and substantially aligned with an outer lateral surface (e.g., the surface 200b) of the substrate 200. In some arrangements, the surface 500b is substantially aligned with an outer lateral surface (e.g., a surface 300b) of the substrate 300. In some arrangements, the portion 500B of the adhesive element 50 has a surface 500a′ exposed to and protruded toward the cavity 10C. In some arrangements, the portion 500B of the adhesive element 50 has a surface 500b′ opposite to the surface 500a′ and substantially aligned with an outer lateral surface (e.g., the surface 200b) of the substrate 200. In some arrangements, the surface 500b′ is substantially aligned with an outer lateral surface (e.g., a surface 300b) of the substrate 300. In some arrangements, the portion 500B covers a portion of the inner sidewall (e.g., the surface 200a′) of the cavity 10C. In some arrangements, the surfaces 500a and 500a′ of the adhesive element 500 are protruded out of or beyond the inner lateral surface (e.g., the surfaces 200a and 200a′) of the substrate 200 (or the sidewall). The protrusions of the adhesive element 500 may be resulted from the thermal-compression operation in which the substrate 300 is pressed toward the substrate 200 and the adhesive element 500 disposed there-between is softened upon heating and then deformed under the pressure. In some arrangements, the adhesive element 500 may be or include an epoxy-based material, e.g., an epoxy-based resin. In some arrangements, the adhesive element 500 includes fillers (not shown). The adhesive element 500 may be referred to as an adhesive resin, an upper adhesive element, or an upper adhesive resin. In some arrangements, the substrate 300 is adhered to the multi-layered substrate (e.g., the combination of the substrates 100 and 200) through the adhesive element 500.

In some arrangements, the alignment mark 600 is disposed or formed on an upper surface or a top surface (e.g., the surface 10a) of the substrate structure 10. In some arrangements, the alignment mark 600 is or includes a conductive pad or a conductive pattern.

In some arrangements, the chip 20 is disposed in the cavity 10C. In some arrangements, the width W2 of the through hole 300T of the substrate 300 is greater than a width W4 of the chip 20. In some arrangements, the chip includes a conductive pad 210. In some arrangements, the chip 20 may be or include a sensor element or a sensing device. In some arrangements, the chip 20 may be or include a microelectromechanical system (MEMS) device. The MEMS device may include micro-sized electromechanical components, for example, switches, mirrors, capacitors, accelerometers, sensors, capacitive sensors, or actuators etc. In some arrangements, the chip 20 includes a MEMS sensor, which includes a membrane separating a sealed cavity from the atmosphere. The MEMS sensor is configured to detect a pressure difference by determining a change in capacitance or resistance due to deformation of the membrane.

In some arrangements, the chip 40 is disposed in the cavity 10C. In some arrangements, the width W2 of the through hole 300T of the substrate 300 is greater than a width W5 of the chip 40. In some arrangements, the chip 40 is adhered to the substrate 100 through an adhesive layer 82, and the chip 20 is adhered to the chip 40 through an adhesive layer 81. The adhesive layers 81 and 82 may be or include die-attach films (DAFs). In some arrangements, the chip 40 includes conductive pads 410, 420, and 430. In some arrangements, the conductive pad 210 of the chip 20 is electrically connected to the conductive pad 410 of the chip 40 through the conductive wire 51. In some arrangements, the conductive pad 420 of the chip 40 is electrically connected to a conductive pad 120A of the conductive layer 120 of the substrate 100 through the conductive wire 52. In some arrangements, the conductive pad 430 of the chip 40 is electrically connected to a conductive pad 120B of the conductive layer 120 of the substrate 100 through the conductive wire 53. The chip 40 may be or include a control integrated circuit (IC) or a processor IC, e.g., an ASIC die.

In some arrangements, the encapsulant 30 encapsulates the chips 20 and 40. The encapsulant 30 may be referred to as a gel. In some arrangements, the encapsulant 30 (or the gel) covers the chip 20 and is spaced apart from the upper surface (e.g., the surface 10a) of the substrate structure 10. In some arrangements, the encapsulant 30 is physically spaced apart from the bottom surface (e.g., the surface 302) of the substrate 300 (or the roof element). In some arrangements, the encapsulant 30 is free from contacting an inner sidewall (e.g., a surface 300a) of the through hole 300T. In some arrangements, the encapsulant 30 is physically spaced apart from an inner sidewall (e.g., a surface 300a) of the through hole 300T. In some arrangements, the substrate 300 (or the cap) is disposed over the substrate 200 (or the sidewall) and configured to block a vertical extending path of the encapsulant 30 (or the gel) in the manufacturing process. In some arrangements, a top surface (e.g., the surface 31) of the encapsulant 30 is lower than a top surface (e.g., a surface 201) of the substrate 200 with respect to the surface 101 of the substrate 100. In some arrangements, the top surface (e.g., the surface 31) includes a concave curved surface. In some arrangements, the cavity 10C includes a portion (e.g., at least a portion of the through hole 200T) filled with the encapsulant 30 and one or more portions (e.g., an upper part of the through hole 200T and the through hole 300T) free of the encapsulant 30. In some arrangements, the width W1 of the portion of the through hole 200T filled with the encapsulant 30 is substantially the same as a width W1′ of the upper part of the through hole 200T free of the encapsulant 30. In some arrangements, the width W2 of the through hole 300T is less than the width W1′ of the upper part of the through hole 200T. In some arrangements, the adhesive element 400 and the encapsulant 30 include different materials. In some arrangements, the adhesive element 500 and the encapsulant 30 include different materials. In some arrangements, the encapsulant 30 includes a silicone-based gel. In some arrangements, the encapsulant 30 is free of fillers. In some arrangements, the encapsulant 30 formed of a silicone-based gel is relatively soft to protect the surface (or the membrane) of the chip 20 (or the MEMS sensor) while still allowing the membrane to deform upon pressure changes.

In some arrangements, the lid 60 is attached to the upper surface (e.g., the surface 10a) of the substrate structure 10 through the adhesive element 70. In some arrangements, the lid 60 is free from contacting the encapsulant 30. In some arrangements, the lid 60 is physically spaced apart from the encapsulant 30. In some arrangements, the lid 60 includes a material different from the material of the substrate 300. In some arrangements, the lid 60 has or defines a through hole 60T (also referred to as “an opening” or “a channel”) over the through hole 300T. In some arrangements, a width W3 of the through hole 60T less than the width W2 of the through hole 300T, and the width W2 of the through hole 300T is less than a width (e.g., the width W1) of the cavity 10C. In some arrangements, the width W4 of the chip 20 is greater than the width W3 of the through hole 60T. In some arrangements, the width W5 of the chip 40 is greater than the width W3 of the through hole 60T. In some arrangements, the lid 60 includes a chimney structure defining the through hole 60T (or the channel) connected to the cavity 10C, and the width W3 of the through hole 60T (or the channel) is less than a thickness W3′ (or “a width”) of a wall of the chimney structure. In some arrangements, an inner sidewall of the chimney structure vertically overlaps the encapsulant 30. In some arrangements, an inner sidewall (e.g., a lateral surface 60a) of the chimney structure vertically overlaps the encapsulant 30. In some arrangements, the inner sidewall (e.g., the lateral surface 60a) of the chimney structure is free from vertically overlapping the barring structure (e.g., the roof element of the substrate 300). In some arrangements, an outer sidewall (e.g., a lateral surface 60b) of the chimney structure vertically overlaps the encapsulant 30. In some arrangements, the outer sidewall (e.g., the lateral surface 60b) of the chimney structure is free from vertically overlapping the barring structure (e.g., the roof element of the substrate 300). In some arrangements, the lid 60 includes a metal lid. According to some arrangements of the present disclosure, with the chimney structure having wall with a relatively large thickness W3′ compared to the width W3 of the through hole 60T of the lid 60, when a pipe used for measuring pressure is placed on the chimney structure of the lid 60, the relatively thick wall of the chimney structure can provide sufficient support and structure strength for the pressure measurement.

In some arrangements, the adhesive element 70 is disposed over the upper surface (e.g., the surface 10a) of the substrate structure 10. In some arrangements, the substrate structure 10 includes a barring structure (e.g., the substrate 300) between the encapsulant 30 and the adhesive element 70 and configured to reduce the contact between the encapsulant 30 and the adhesive element 70. In some arrangements, the adhesive element 70 is between and contacts the substrate 300 (or the roof element) and the lid 60. In some arrangements, a top surface (e.g., a surface 201) of the chip 20 is at an elevation lower than an elevation of the adhesive element 70 with respect to the upper surface (e.g., the surface 10a) of the substrate structure 10. In some arrangements, an elevation of the adhesive element 70 is higher than an elevation of a top surface (e.g., the surface 201) of the chip 20 with respect to a bottom surface (e.g., a surface 202) opposite to the top surface of the chip 20. In some arrangements, an elevation of an upper surface (e.g., a surface 701) of the adhesive element 70 that is attached to the lid 60 is higher than an elevation of an upper surface (e.g., the surface 201) of the chip 20 with respect to a lower surface (e.g., a surface 202) opposite to the upper surface of the chip 20. In some arrangements, the adhesive element 70 overlaps the encapsulant 30 in a direction substantially perpendicular to the surface 10a of the substrate structure 10. In some arrangements, an elevation of a bottom surface (e.g., a surface 702) of the adhesive element 70 is higher than an elevation of a top surface (e.g., the surface 31) of the encapsulant 30 (or the gel) with respect to an upper surface (e.g., the surface 101) of the substrate 100. In some arrangements, a width of the adhesive element 70 is less than a width of the top surface (e.g., the surface 10a) of the substrate structure 10. In some arrangements, a width of the adhesive element 70 is less than a width of a bottom surface of the lid 60. In some arrangements, a gap is between the adhesive element 70 and the encapsulant 30 in a direction substantially perpendicular to an upper surface (e.g., the surface 10a) of the substrate 300. In some arrangements, the encapsulant 30 is physically spaced apart from the adhesive element 70. In some arrangements, the encapsulant 30 is physically spaced apart from the adhesive element 70 by the substrate 300 (or the roof element). In some arrangements, the adhesive element 70 is not horizontally overlapped with the encapsulant 30. In some arrangements, the adhesive element 70 vertically overlaps the encapsulant 30. In some arrangements, a hardness of the adhesive element 70 is greater than a hardness of the encapsulant 30. In some arrangements, a modulus of the adhesive element 70 is greater than a modulus of the encapsulant 30. In some arrangements, the adhesive elements 400, 500, and 70 include at least an epoxy-based resin, and the encapsulant 30 includes a silicone-based material. In some arrangements, the adhesive element 70 includes fillers (not shown). In some arrangements, the epoxy-based resin of the adhesive elements 400, 500, and 70 can provide a relatively strong adhesion between the substrates or between the substrate and the lid 60.

In some cases where a MEMS sensor is disposed in a cavity formed by a molding compound, for example, an epoxy-based molded structure, after a silicone-based gel is filled in the cavity to cover the membrane of the MEMS sensor, a metal lid is then attached to the top surface of the molded structure. However, the silicone-based gel may overflow to cover some regions of the top surface of the molded structure on which adhesive elements are supposed to be disposed to adhere the metal lid to the molded structure. As a result, the metal lid may fail to attach to the molded structure due to that the silicone-based gel occupies the attaching areas instead of the adhesive element, or the molded structure has to be made with a relatively large top surface in order to provide tolerance area for the overflow of the silicon-based gel, which may lead to an increase of the package size.

In contrast, according to some arrangements of the present disclosure, the chip 20 is disposed in the cavity 10C defined by substrates laminated to each other instead of a molded structure, and the top surface of the laminated substrates is spaced apart from the encapsulant 30 that covers the chip 20. Therefore, the adhesive element 70 used for attaching the lid 60 to the laminated substrates can be disposed on the top surface without reserving spare spaces for overflow tolerance or overflow control, thus the area (e.g., the area in x-y directions) of the package structure can be reduced, and the package size can be reduced as well.

Moreover, in some cases where molded structures are formed by disposing molding materials on a substrate strip, the interfaces between the molding materials and the substrate strip may cause warpage of the strip structure. In order to reduce the warpage from the interfaces, tolerance spaces are required between the molded structures to form separated mold areas for respective molded structures, and thus the strip density is reduced. In contrast, according to some arrangements of the present disclosure, the cavity is defined by laminated substrates instead of a molded structure, delicate mold tools used for manufacturing molded structures can be omitted, thus the manufacturing process can be simplified, and the cost can be reduced. In addition, molding materials are not used, thus the tolerance spaces for reducing warpage of the substrate strip can be omitted. Therefore, the strip density can be increased significantly, for example, by about 150%. Furthermore, the process for forming alignment marks for aligning the lid 60 to the substrate structure 10 can be integrated in the process for forming the substrate, and thus the placement of the lid 60 can be accomplished with a reduced alignment shift while the overall process remains simplified.

In addition, according to some arrangements of the present disclosure, the adhesive element 70 connects the lid 60 to the top surface of the laminated substrates and is spaced apart from the encapsulant 30 that covers the chip 20. Therefore, the lid 60 can be attached to the top surface of the substrate structure 10 without being adversely affected by the poor adhesion between the heterogeneous materials of the adhesive element 70 and the encapsulant 30. Therefore, the stability and the reliability of the package structure can be improved while the package size is reduced. Moreover, the substrate structure 10 includes a roof element, thus the adhesive element 70 can be spaced apart from the encapsulant 30 by the roof element, and the roof element can also provide an enlarge area for disposing the adhesive element 70 and the alignment mark 600.

Furthermore, in some cases wherein a silicone-based gel is used to cover the membrane of a MEMS sensor on a substrate, and an epoxy-based adhesive is used to adhere a metal lid to the substrate to accommodate the MEMS chip in the space provided by the metal lid. However, the silicone-based gel may contact the epoxy-based adhesive, and the relatively poor adhesion between the silicone-based gel and the epoxy-based adhesive may reduce the stability of the package structure. In contrast, according to some arrangements of the present disclosure, the encapsulant 30 is spaced apart from the adhesive element 70, such that the aforesaid issue can be solved, and thus the stability and reliability of the package structure can be increased.

FIG. 1C is a top view of a package structure 1C in accordance with some arrangements of the present disclosure. In some arrangements, the package structure 1C has a structure similar to the structure illustrated in FIG. 1B, with differences therebetween as follows.

In some arrangements, the substrate structure 10 includes a pair of alignment marks 600 at corners of the upper surface of the substrate structure 10. In some arrangements, the conductive pads 420 and 430 are on opposite sides of the chip 20. In some arrangements, the conductive wires 52 and 53 are on opposite sides of the chip 20. In some arrangements, the conductive pads 120A and 120B are on opposite sides of the chip 20.

FIG. 1D is a cross-section of a package structure 1D in accordance with some arrangements of the present disclosure. In some arrangements, the package structure 1D has a structure similar to the structure illustrated in FIG. 1A, with differences therebetween as follows.

In some arrangements, the encapsulant 30 (or the gel) contacts the adhesive element 500. In some arrangements, the encapsulant 30 contacts the bottom surface (e.g., the surface 302) of the substrate 300. In some arrangements, at least a portion of a top surface (e.g., the surface 31) of the encapsulant 30 is higher than the top surface (e.g., a surface 201) of the substrate 200 with respect to the surface 101 of the substrate 100.

In some arrangements, the cavity 10C includes a portion (e.g., at least a portion of the through hole 200T) filled with the encapsulant 30 and one or more portions (e.g., an upper part of the through hole 200T and the through hole 300T) free of the encapsulant 30. In some arrangements, the width W1 of the portion of the through hole 200T filled with the encapsulant 30 is greater than a width W1′ of the upper part of the through hole 200T free of the encapsulant 30. In some arrangements, the width W2 of the through hole 300T is less than the width W1′ of the upper part of the through hole 200T. In some arrangements, the encapsulant 30 in the upper part of the through hole 200T contacts the surface 302 of the substrate 300. In some arrangements, a width (i.e., the width W1′) of the surface 31 of the encapsulant 30 free from contacting the surface 302 is less than the width W1 of the through hole 200T.

In some arrangements, the adhesive element 70 includes a portion 710 adjacent to the alignment mark 600 and a portion 720 distal from the alignment mark 600 and separated from the portion 710, and a width of the portion 720 is greater than a width of the portion 710. According to some arrangements of the present disclosure, the portion 710 adjacent to the alignment mark 600 has a relatively small width can provide an increased tolerance area for preventing the adhesive element 70 from covering the alignment mark 600. Therefore, the alignment mark 600 can be exposed by the adhesive element 70 and the lid 60, such that the alignment accuracy of the lid 60 with the substrate structure 10 can be retested by detecting the relative position of the alignment mark 600 and the lid 60 to confirm whether the package structure 1D is manufactured as expected.

In some arrangements, an elevation of a top surface (e.g., the surface 701) of the adhesive element 70 (e.g., the portion 720) is higher than an elevation of a bottom surface (e.g., a surface 602) of the lid 60 with respect to the surface 10a of the substrate structure 10. In some arrangements, a portion (e.g., the portion 720) of the adhesive element 70 extends over an outer lateral surface (e.g., the lateral surface 60b) of the lid 60. In some arrangements, the adhesive element 70 is free from contacting an inner lateral surface (e.g., the lateral surface 60a) of the lid 60. In some arrangements, the width or the volume of the portion 710 is less than that of the portion 720 for reserving the tolerance area for the alignment mark 600. Therefore, after the lid 60 is attached to the substrate structure 10, the portion 720 may be pressed to extend and protrude out of the space between the lid 60 and the surface 10a of the substrate structure 10, and thus the portion 720 may further extend over an outer lateral surface (e.g., the lateral surface 60b) of the lid 60. According to some arrangements of the present disclosure, with the portion 720 further covering and contacting at least a portion of the outer lateral surface (e.g., the lateral surface 60b) of the lid 60, the attachment between the lid 60 and the substrate structure 10 can be increased, and thus the structural strength and reliability of the package structure 1D can be increased.

FIG. 1E is a cross-section of a package structure 1E in accordance with some arrangements of the present disclosure. In some arrangements, the package structure 1E has a structure similar to the structure illustrated in FIG. 1A, with differences therebetween as follows.

In some arrangements, the top surface (e.g., the surface 31) of the encapsulant 30 includes a curved surface. The surface 31 includes a plurality of concave portions and a plurality of convex portions. In some arrangements, a portion of the encapsulant 30 contacts the surface 302 of the substrate 300.

In some arrangements, the portions 710 and 720 extend over the lateral surfaces 60b of the lid 60 by different lengths. In some arrangements, an elevation of the top surface of the portion 710 is lower than an elevation of the top surface of the portion 720 with respect to the surface 10a.

FIG. 1F is a cross-section of a package structure 1F in accordance with some arrangements of the present disclosure. In some arrangements, the package structure 1F has a structure similar to the structure illustrated in FIG. 1A, with differences therebetween as follows.

In some arrangements, an outer lateral surface 70a of the adhesive element 70 is substantially aligned with the lateral surface 60b of the lid 60 and the surface 300b of the substrate 300.

FIG. 1G is a cross-section of a package structure 1G in accordance with some arrangements of the present disclosure. In some arrangements, the package structure 1G has a structure similar to the structure illustrated in FIG. 1A, with differences therebetween as follows.

In some arrangements, the substrate structure 10 includes the substrates 100 and 200. In some arrangements, the substrate 200 includes a molding layer or a bulk substrate having the through hole 200T tapering toward the substrate 100. In some arrangements, the surface 200a of the substrate 200 is inclined so as to serve as a barring structure between the encapsulant 30 and the adhesive element 70 and configured to reduce the contact between the encapsulant 30 and the adhesive element 70.

FIG. 1H is a cross-section of a package structure 1H in accordance with some arrangements of the present disclosure. In some arrangements, the package structure 1H has a structure similar to the structure illustrated in FIG. 1A, with differences therebetween as follows.

In some arrangements, the substrate structure 10 includes the substrates 100 and 200. In some arrangements, the substrate 200 includes a molding layer or a bulk substrate. In some arrangements, the substrate 200 is relatively tall, such that an upper portion of the substrate 200 may serve as barring structure between the encapsulant 30 and the adhesive element 70 and configured to reduce the contact between the encapsulant 30 and the adhesive element 70.

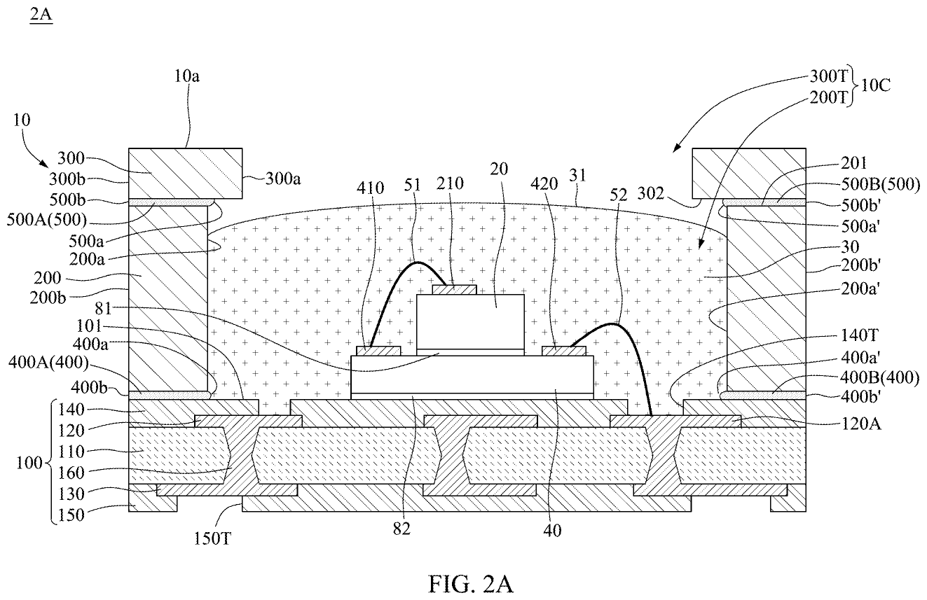

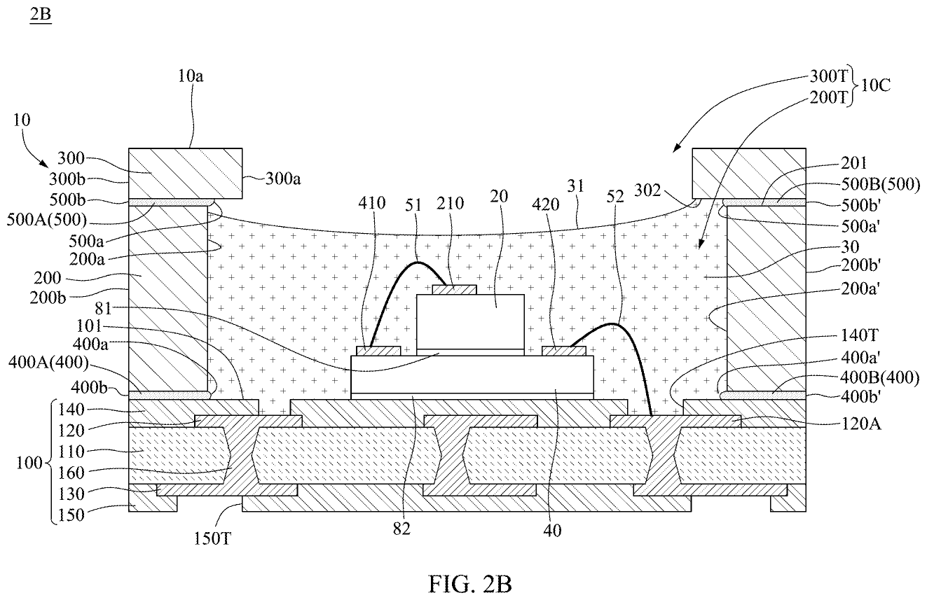

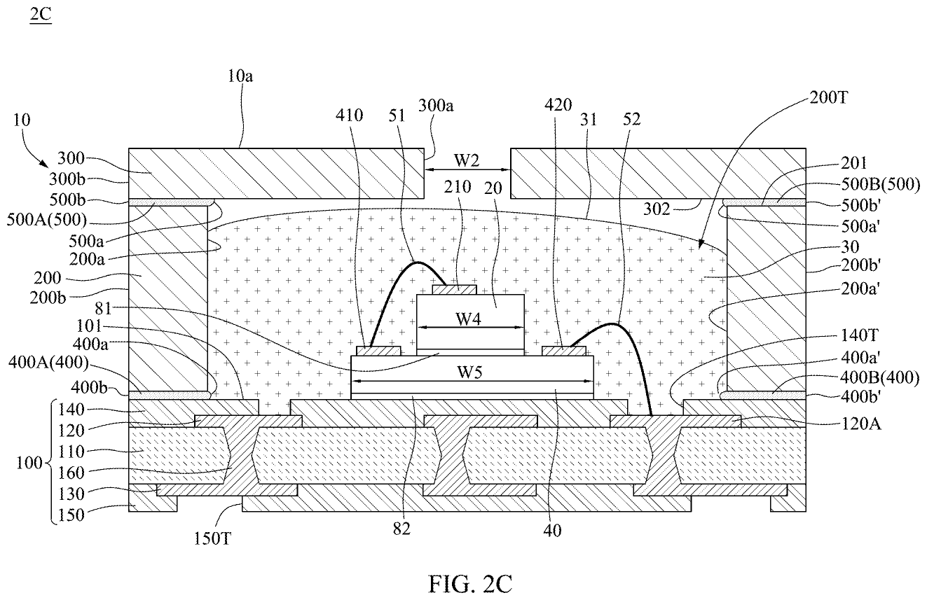

FIG. 2A is a cross-section of a package structure 2A in accordance with some arrangements of the present disclosure. In some arrangements, the package structure 2A has a structure similar to the structure illustrated in FIG. 1A, with differences therebetween as follows.

In some arrangements, the package structure 2A does not include an alignment mark 600, the adhesive element 70, and the lid 60 over the upper surface (e.g., the surface 10a) of the substrate structure 10. In some arrangements, the top surface (e.g., the surface 31) of the encapsulant 30 includes a convex curved surface.

FIG. 2B is a cross-section of a package structure 2B in accordance with some arrangements of the present disclosure. In some arrangements, the package structure 2B has a structure similar to the structure illustrated in FIG. 1D, with differences therebetween as follows.

In some arrangements, the package structure 2B does not include an alignment mark 600, the adhesive element 70, and the lid 60 over the upper surface (e.g., the surface 10a) of the substrate structure 10. In some arrangements, the top surface (e.g., the surface 31) of the encapsulant 30 includes a concave curved surface. In some arrangements, a center line of the concave curved surface is misaligned with a center line of the through hole 200T.

FIG. 2C is a cross-section of a package structure 2C in accordance with some arrangements of the present disclosure. In some arrangements, the package structure 2C has a structure similar to the structure illustrated in FIG. 2A, with differences therebetween as follows.

In some arrangements, the width W2 of the through hole 300T of the substrate 300 is less than the width W4 of the chip 20 and the width W5 of the chip 40. In some arrangements, the top surface (e.g., the surface 31) of the encapsulant 30 includes a convex curved surface. In some arrangements, a center line of the convex curved surface is misaligned with a center line of the through hole 200T.

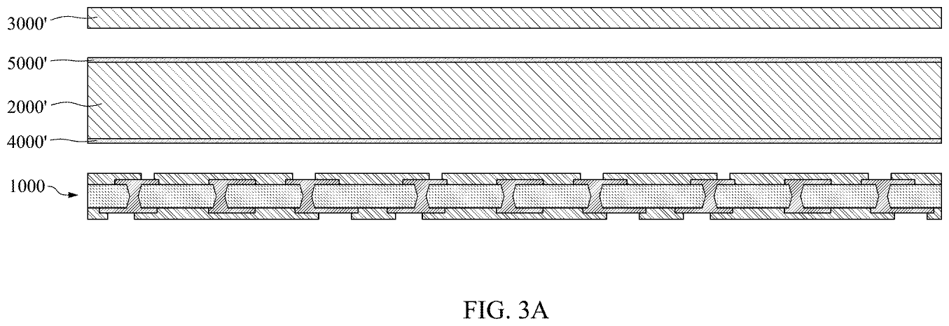

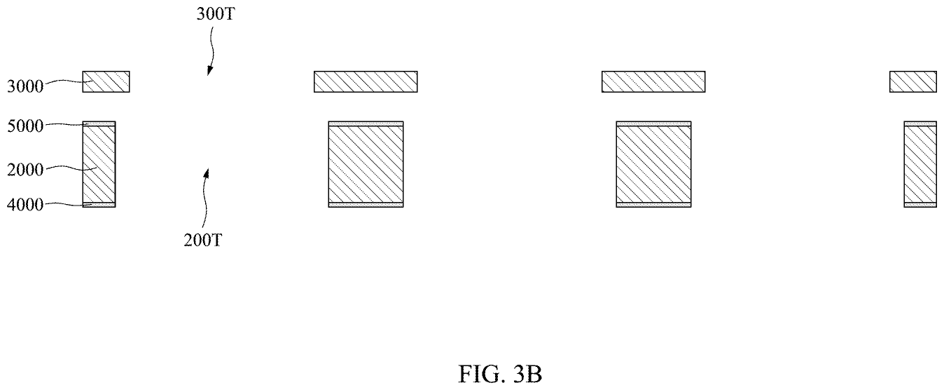

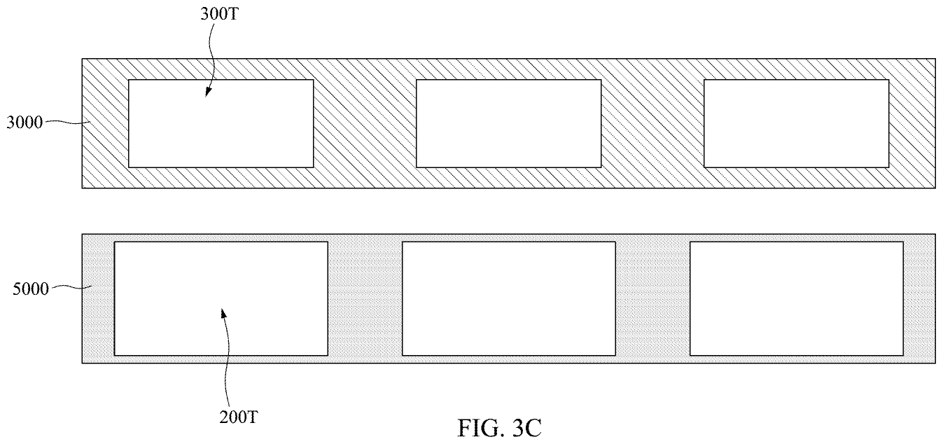

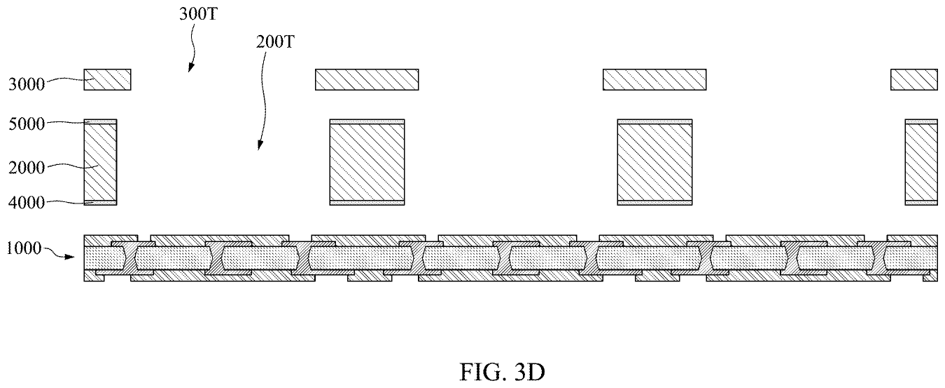

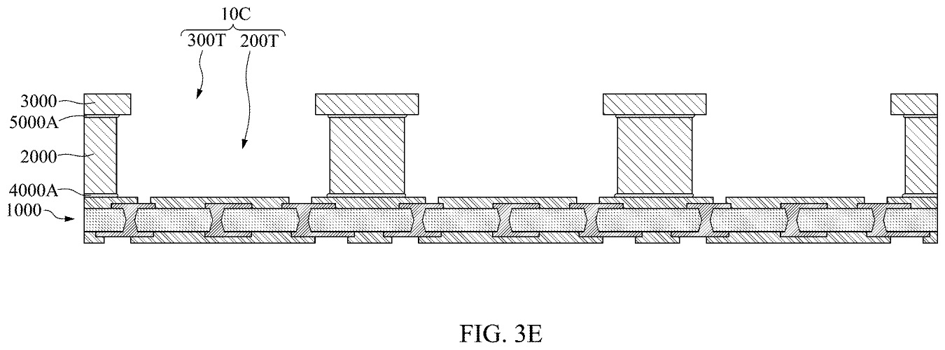

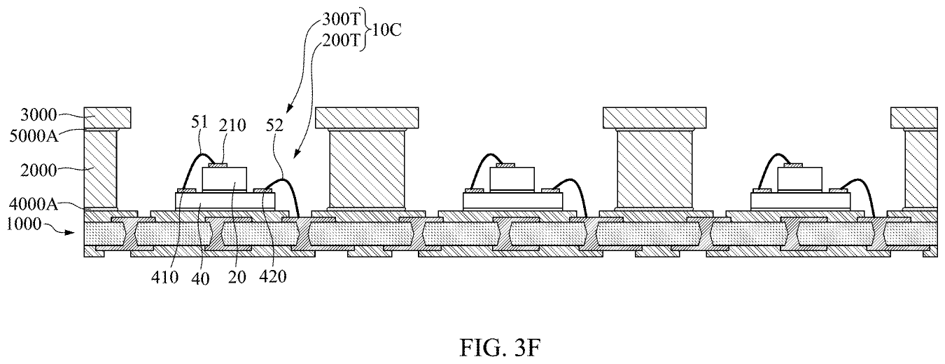

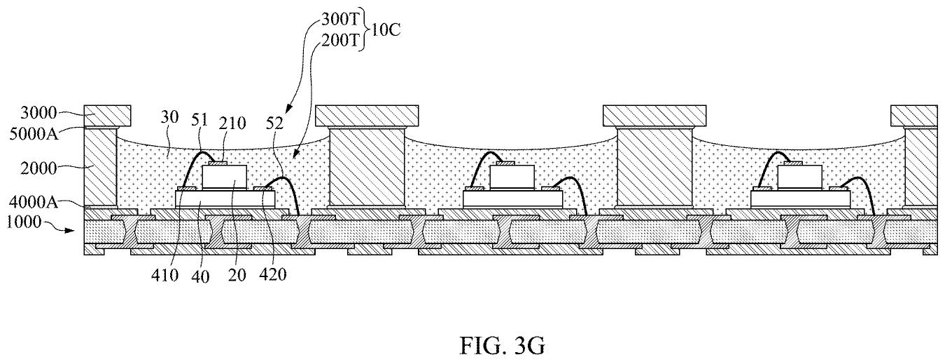

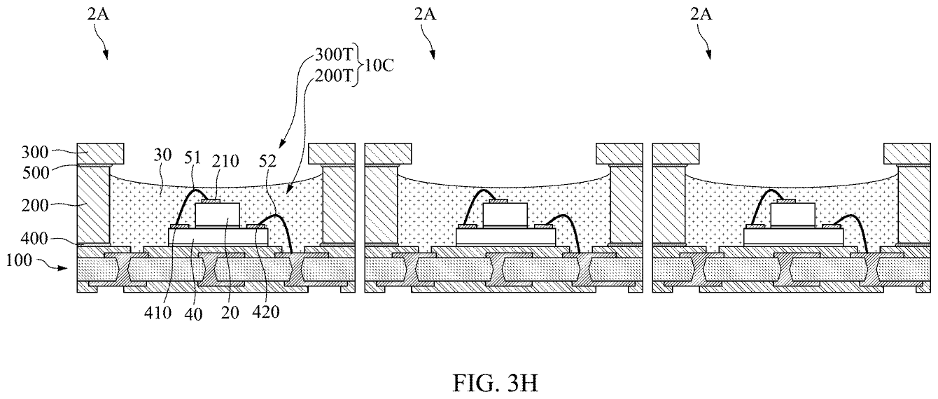

FIG. 3A, FIG. 3B, FIG. 3C, FIG. 3D, FIG. 3E, FIG. 3F, FIG. 3G, and FIG. 3H illustrate various stages of an exemplary method for manufacturing a package structure 2A in accordance with some arrangements of the present disclosure.

Referring to FIG. 3A, substrates 1000, 2000′ and 3000′ may be provided, and adhesive elements 4000′ and 5000′ may be formed on opposite surfaces of the substrate 2000′. In some arrangements, referring to FIG. 2A, the substrate 1000 includes a core layer 110, conductive layers 120 and 130, dielectric layers 140 and 150, and a conductive structure 160. In some arrangements, copper foils may be removed from surfaces of the substrates 2000′ and 3000′ prior to forming the adhesive elements 4000′ and 5000′ on the surfaces of the substrate 2000′. The copper foils may be removed by etching. The adhesive elements 4000′ and 5000′ may be formed on the surfaces of the substrate 2000′ by lamination.

Referring to FIG. 3B and FIG. 3C, FIG. 3C is a top view of the structure illustrated in FIG. 3B, a removal operation may be performed on the substrate 2000′ to form a substrate 2000 including through holes 200T, and a removal operation may be performed on the substrate 3000′ to form a substrate 3000 including through holes 300T. In some arrangements, portions of the adhesive elements 4000′ and 5000′ may be removed to form adhesive elements 4000 and 5000 having through holes aligned with the through holes 200T.

Referring to FIG. 3D, the substrates 2000 and 3000 may be stacked over the substrate 1000.

Referring to FIG. 3E, a thermoforming operation may be performed to adhere the substrates 1000, 2000, and 3000 through the adhesive elements 4000 and 5000. In some arrangements, the adhesive elements 4000 and 5000 may soften and deform to form adhesive elements 4000A and 5000A that connect the substrates 1000, 2000, and 3000 to each other. In some arrangements, portions of the adhesive elements 4000A and 5000A may be softened and protruded into the cavity 10C defined by the through holes 200T and 300T.

Referring to FIG. 3F, chips 20 and 40 may be disposed in the cavities 10C. In some arrangements, the chip 40 is adhered to the substrate 1000, and the chip 20 is adhered to the chip 40. In some arrangements, conductive wires 51 may be provided to electrically connect the chips 20 to the chips 40. In some arrangements, conductive wires 52 may be provided to electrically connect the chips 40 to the substrate 1000.

Referring to FIG. 3G, encapsulants 30 may be filled in the cavities 10C to encapsulate the chips 20 and 40.

Referring to FIG. 3H, a singulation operation may be performed to form the package structures 2A. In some arrangements, the singulation operation may be performed on the substrates 1000, 2000, 3000, and the adhesive elements 4000A and 5000A. As such, the package structure 2A illustrated in FIG. 2A may be formed.

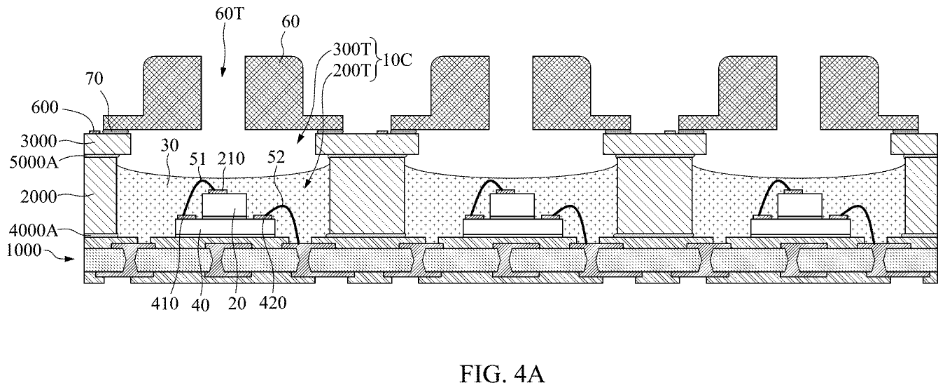

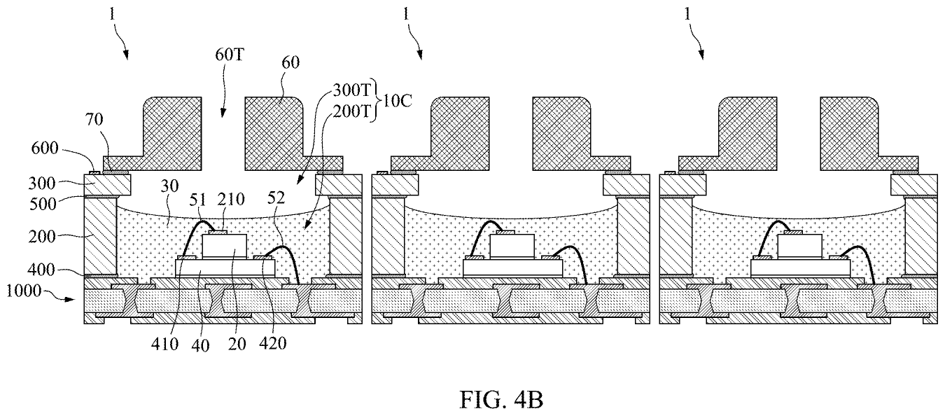

FIG. 4A and FIG. 4B illustrate various stages of an exemplary method for manufacturing a package structure 1 in accordance with some arrangements of the present disclosure.

Referring to FIG. 4A, operations similar to those illustrated in FIGS. 3A-3G may be performed to form a structure illustrated in FIG. 3G, alignment marks 600 may be formed on an upper surface of the substrate 1000, and lids 60 may be attached to the upper surface of the substrate 1000 through adhesive elements 70.

Referring to FIG. 4B, a singulation operation may be performed to form the package structures 1. In some arrangements, the singulation operation may be performed on the substrates 1000, 2000, 3000, and the adhesive elements 4000A and 5000A. As such, the package structure 1 illustrated in FIGS. 1A-1B may be formed.

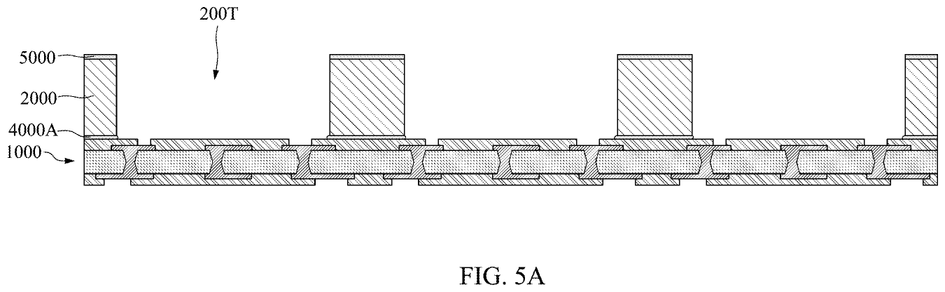

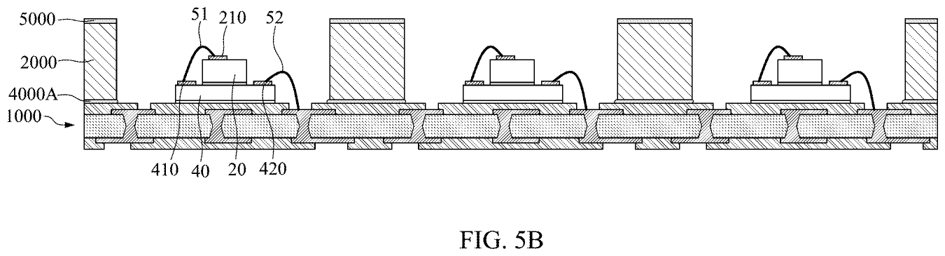

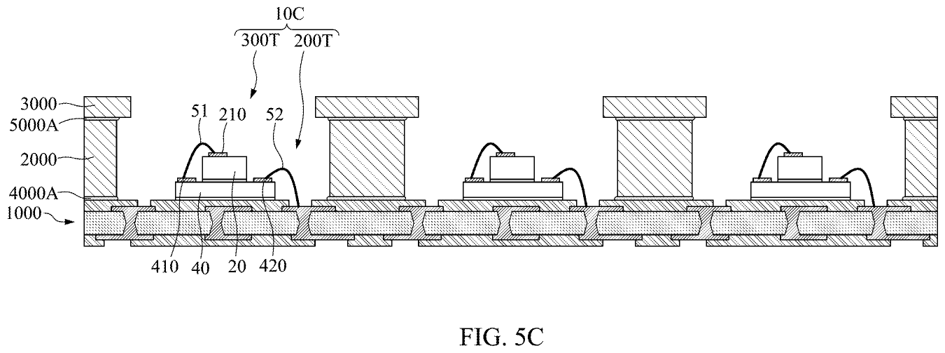

FIG. 5A, FIG. 5B, and FIG. 5C illustrate various stages of an exemplary method for manufacturing a package structure 2A in accordance with some arrangements of the present disclosure.

Referring to FIG. 5A, operations similar to those illustrated in FIGS. 3A-3C may be performed to provide a substrate 1000 and a substrate 2000 having through holes 200T with adhesive elements 4000 and 5000 on surfaces of the substrate 2000, and a thermoforming operation may be performed to adhere the substrate 2000 to the substrate 1000 through the adhesive element 4000. In some arrangements, the adhesive element 4000 may soften and deform to form an adhesive element 4000A that connects the substrates 1000 and 2000 to each other. In some arrangements, portions of the adhesive element 4000A may be softened and protruded into the through holes 200T.

Referring to FIG. 5B, chips 20 and 40 may be disposed in the through holes 200T. In some arrangements, the chip 40 is adhered to the substrate 1000, and the chip 20 is adhered to the chip 40. In some arrangements, conductive wires 51 may be provided to electrically connect the chips 20 to the chips 40. In some arrangements, conductive wires 52 may be provided to electrically connect the chips 40 to the substrate 1000.

Referring to FIG. 5C, operations similar to those illustrated in FIGS. 3A-3C may be performed to provide a substrate 3000 having through holes 300T, a thermoforming operation may be performed to adhere the substrate 3000 to the substrate 2000 through the adhesive element 5000. In some arrangements, the adhesive element 5000 may soften and deform to form an adhesive element 5000A that connects the substrates 2000 and 3000 to each other. In some arrangements, portions of the adhesive element 5000A may be softened and protruded into cavities 10C defined by the through holes 200T and 300T.

Next, operations similar to those illustrated in FIGS. 3G-3H may be performed to fill encapsulants 30 in the cavities 10C and singulate the strip-form structure to form the package structures 2A.

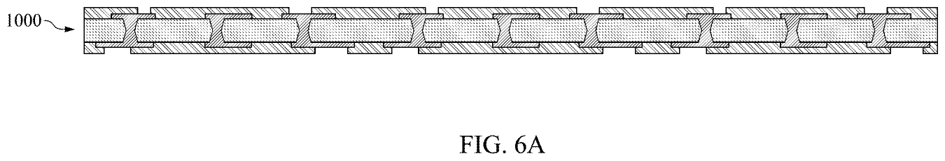

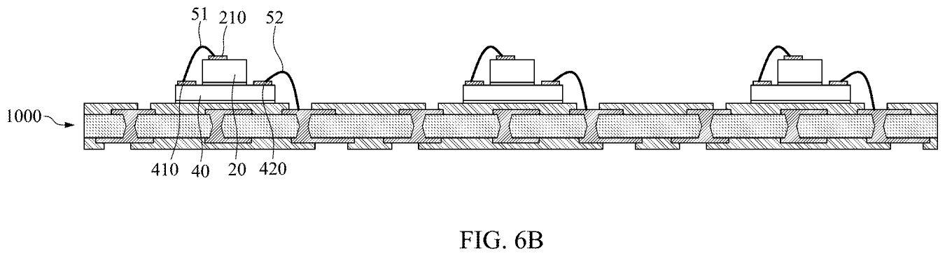

FIG. 6A and FIG. 6B illustrate various stages of an exemplary method for manufacturing a package structure 2A in accordance with some arrangements of the present disclosure.

Referring to FIG. 6A, a substrate 1000 may be provided.

Referring to FIG. 6B, chips 20 and 40 may be disposed on the substrate 1000. In some arrangements, the chip 40 is adhered to the substrate 1000, and the chip 20 is adhered to the chip 40. In some arrangements, conductive wires 51 may be provided to electrically connect the chips 20 to the chips 40. In some arrangements, conductive wires 52 may be provided to electrically connect the chips 40 to the substrate 1000.

Next, operations similar to those illustrated in FIGS. 3A-3E may be performed to laminate the substrates 2000 and 3000 to the substrate 1000. Next, operations similar to those illustrated in FIGS. 3G-3H may be performed to fill encapsulants 30 in the cavities 10C and singulate the strip-form structure to form the package structures 2A.

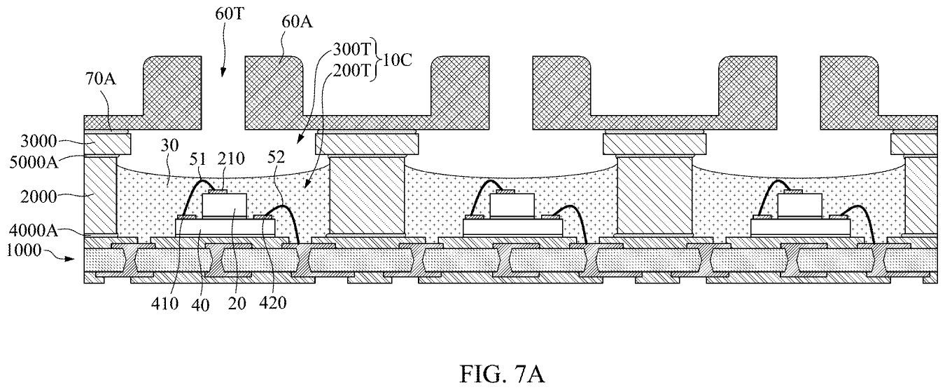

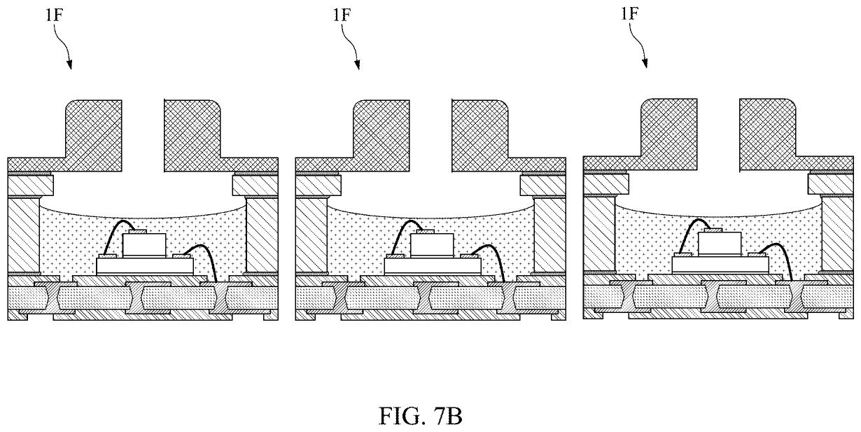

FIG. 7A and FIG. 7B illustrate various stages of an exemplary method for manufacturing a package structure 1F in accordance with some arrangements of the present disclosure.

Referring to FIG. 7A, operations similar to those illustrated in FIGS. 3A-3G may be performed to form a structure illustrated in FIG. 3G, and a lid layer 60A may be attached to the upper surface of the substrate 1000 through adhesive elements 70A.

Referring to FIG. 7B, a singulation operation may be performed to form the package structures 1F. In some arrangements, the singulation operation may be performed on the lid layer 60A, the substrates 1000, 2000, 3000, and the adhesive elements 70A, 4000A, and 5000A. As such, the package structure 1A illustrated in FIG. 1F may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a substrate structure defining a cavity;
a chip disposed in the cavity;
an encapsulant encapsulating the chip; and
an adhesive element disposed over a top surface of the substrate structure, wherein the substrate structure comprises a barring structure between the encapsulant and the adhesive element and configured to reduce a contact between the encapsulant and the adhesive element.

2. The package structure as claimed in claim 1, wherein the barring structure comprises a roof element, the roof element defines a through hole connecting the cavity to outside the cavity and overlapping the chip in a direction substantially perpendicular to the top surface of the substrate structure.

3. The package structure as claimed in claim 2, wherein a bottom surface of the roof element defines an inner top surface of the cavity.

4. The package structure as claimed in claim 2, wherein the encapsulant is physically spaced apart from the adhesive element by the roof element.

5. The package structure as claimed in claim 2, wherein the encapsulant is free from contacting an inner sidewall of the through hole.

6. The package structure as claimed in claim 1, further comprising a lid attached to the top surface of the substrate structure through the adhesive element, wherein an elevation of the adhesive element is higher than an elevation of a top surface of the chip with respect to a bottom surface opposite to the top surface of the chip.

7. The package structure as claimed in claim 6, wherein the encapsulant does not contact the lid.

8. A package structure, comprising:
a substrate structure comprising a lower substrate, a middle substrate, and an upper substrate laminated to each other and collectively defining a cavity;
a sensing device disposed in the cavity; and
a gel covering the sensing device and spaced apart from an upper surface of the substrate structure.

9. The package structure as claimed in claim 8, wherein the lower substrate supports the sensing device, and the upper substrate defines an opening over and overlapping the sensing device in a direction substantially perpendicular to the upper surface of the substrate structure.

10. The package structure as claimed in claim 9, wherein the middle substrate has a through hole, and the opening and the through hole collectively define the cavity of the substrate structure.

11. The package structure as claimed in claim 10, wherein a width of the opening is less than a width of the through hole in a cross-sectional view.

12. The package structure as claimed in claim 8, further comprising a lid attached to a top surface of the upper substrate through an adhesive element, and the adhesive element overlaps the gel in a direction substantially perpendicular to the upper surface of the substrate structure.

13. The package structure as claimed in claim 12, wherein an elevation of a top surface of the adhesive element is higher than an elevation of a bottom surface of the lid with respect to the upper surface of the substrate structure.

14. The package structure as claimed in claim 12, wherein an elevation of a bottom surface of the adhesive element is higher than an elevation of a top surface of the gel with respect to an upper surface of the lower substrate.

15. The package structure as claimed in claim 12, wherein the lid has an opening having a first width and attached to the upper substrate through the adhesive element, and the upper substrate has an opening having a second width greater than the first width.

16. The package structure as claimed in claim 12, wherein the substrate structure further comprises an alignment mark on the upper surface of the substrate structure, and wherein in a cross-sectional view perspective, the adhesive element comprises a first portion adjacent to the alignment mark and a second portion distal from the alignment mark and separated from the first portion, and a width of the second portion is greater than a width of the first portion.

17. A package structure, comprising:
a substrate;
a sidewall disposed over the substrate, the sidewall and the substrate collectively defining a cavity;
a chip disposed in the cavity;
an encapsulant disposed in the cavity and encapsulating the chip; and
a cap disposed over the sidewall, wherein an outer lateral surface of the sidewall is substantially aligned with a lateral surface of the substrate.

18. The package structure as claimed in claim 17, further comprising an adhesive adhering the sidewall to the substrate, wherein an outer lateral surface of the adhesive is substantially aligned with the outer lateral surface of the sidewall and the lateral surface of the substrate.

19. The package structure as claimed in claim 17, wherein an outer lateral surface of the cap is substantially aligned with the outer lateral surface of the sidewall.

20. The package structure as claimed in claim 19, further comprising an adhesive adhering the cap to the sidewall, wherein an outer lateral surface of the adhesive is substantially aligned with the outer lateral surface of the cap and the outer lateral surface of the sidewall.
